(19) United States
(12) Patent Application Publication
(10) Pub. No.: US 2014/0117994 A1
(43) Pub. Date: May 1, 2014

(54) CALIBRATING A LIGHTING DEVICE COMPRISING A SEMICONDUCTOR LIGHT SOURCE

(71) Applicant: OSRAM GmbH, Muenchen (DE)

(72) Inventor: Andreas Biebersdorf, Regensburg (DE)

(73) Assignee: OSRAM GmbH, Muenchen (DE)

(21) Appl. No.: 14/065,470

(22) Filed: Oct. 29, 2013

(30) Foreign Application Priority Data
Oct. 30, 2012 (DE) 10 2012 219 876.8

(51) Int. Cl. G01R 31/44

(52) U.S. Cl. CPC G01R 31/44
USPC 324/414

(57) ABSTRACT

In various embodiments, a method for calibrating a lighting device is provided. The lighting device may include at least one semiconductor light source. The method may include: determining a thermal power loss of the at least one semiconductor light source; determining an electrical power of the at least one semiconductor light source; and determining a light power of the at least one semiconductor light source from the electrical power and the thermal power loss.

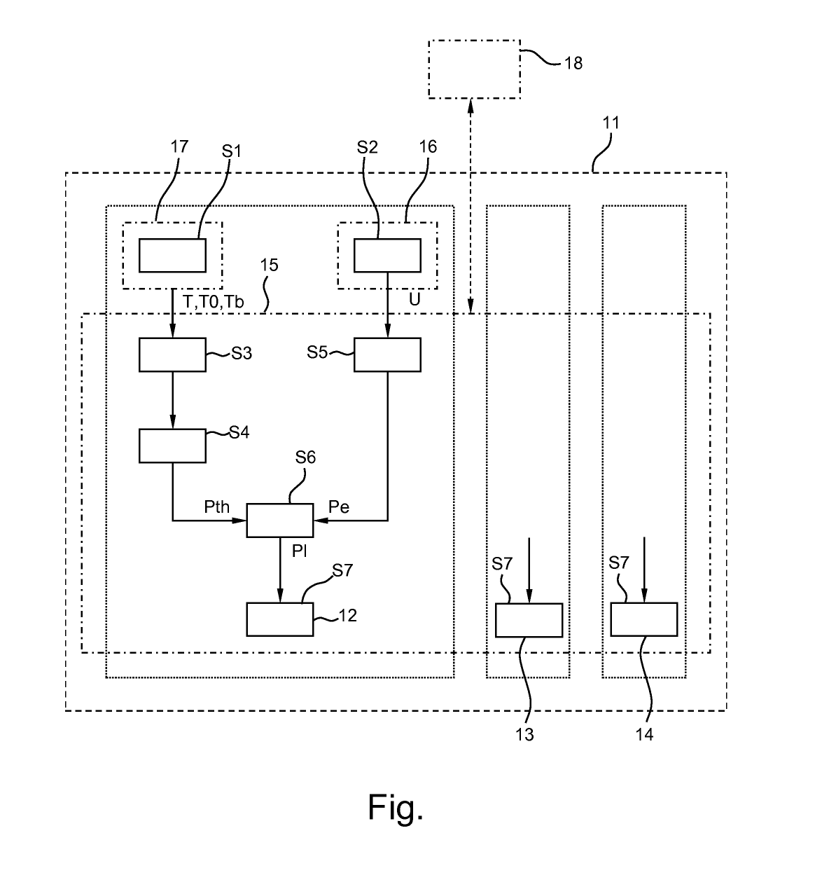

### CROSS-REFERENCE TO RELATED APPLICATION

This application claims priority to German Patent Application Ser. No. 10 2012 219 876.8, which was filed Oct. 30, 2012, and is incorporated herein by reference in its entirety.

### TECHNICAL FIELD

Various embodiments relate generally to a method for calibrating a lighting device including at least one semiconductor light source. Various embodiments also relate to a lighting device including at least one semiconductor light source, wherein the lighting device is designed for independently carrying out the method. Various embodiments are applicable e.g. to LED lighting devices, e.g. LED lamps and LED modules.

### BACKGROUND

If, for the purpose of generating light, the intention is to use light emitting diodes (LEDs) which emit light of different colors (e.g. RGB, “Brilliant Mix” from Osram Opto Semiconductors and much more), the respective brightnesses have to be well coordinated with one another in order to achieve a specific cumulative color locus of the mixed light from the differently colored light. This coordination changes with temperature (different temperature response of the LEDs) and with time (different ageing of the LEDs). The ageing, in particular, cannot be predicted during production.

Lighting devices of the relevant type are known which do not provide closed-loop control of the brightnesses of the LEDs, with the result that an appreciable change in the cumulative color locus is accepted in the case of these lighting devices. This is disadvantageous in particular when a plurality of such lighting devices are arranged alongside one another, since the human eye can clearly perceive even just slight color deviations.

Lighting devices of the relevant type are also known which have closed-loop control, in which a temperature of the LEDs is measured and corrected with known or estimated temperature dependencies.

Optionally, a predefined (but not necessarily realistic) ageing behavior can be corrected, e.g. by means of a corresponding characteristic curve of the power to be impressed over the operating period. Such lighting devices have the disadvantage that their correction or calibration of the brightnesses can deviate in some instances considerably from the actually required correction in the real installation situation present.

Moreover, lighting devices of the relevant type are known which carry out closed-loop control or calibration with the aid of a color sensor or brightness sensor: in this case, the light intensity for each color component is measured and correspondingly corrected. This variant hitherto has been the only one which can reliably bring about the desired color locus. However, the at least one sensor required for this is expensive, and, moreover, ageing of the sensor is an unknown fault source.

### SUMMARY

In various embodiments, a method for calibrating a lighting device is provided. The lighting device may include at least one semiconductor light source. The method may include: determining a thermal power loss of the at least one semiconductor light source; determining an electrical power of the at least one semiconductor light source; and determining a light power of the at least one semiconductor light source from the electrical power and the thermal power loss.

### BRIEF DESCRIPTION OF THE DRAWINGS

The above-described properties, features and advantages of this invention and the way in which they are achieved will become clearer and more clearly understandable in connection with the following schematic description of an embodiment explained in greater detail in association with a drawing.

The FIGURE shows a lighting device in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments may at least partly overcome the disadvantages of the prior art.

Various embodiments provide a method for calibrating a lighting device, including at least one semiconductor light source, wherein the method includes at least the following steps: determining a thermal power loss, Pth, of the at least one semiconductor light source; determining an electrical power, Pe, of the at least one semiconductor light source; and determining a light power, Pl, of the at least one semiconductor light source from the electrical power and the thermal power loss.

This method may have the advantage that it enables a precise and nevertheless inexpensively implementable stabilization of a color locus and/or light power or brightness of the at least one semiconductor light source. In various embodiments, on the one hand it is possible to dispense with a color sensor, and on the other hand it is possible to achieve a more precise determination of an actual light power than just in the case of a temperature determination. As a result, in particular, an age-dependent change, e.g. degradation, of the light power can also be determined sufficiently precisely and if desired corrected in a simple manner.

Calibration may be understood to mean, in particular, reliably reproducible measurement for ascertaining a deviation of a measured value of a parameter (e.g. light power or brightness) with respect to a desired value or normal value of said parameter. The calibration may optionally include taking account of the deviation during subsequent operation of the lighting device, in particular by correcting the measured values to the desired value. The method may also simply be designated as a method for operating a lighting device.

In various embodiments, the at least one semiconductor light source includes at least one light emitting diode. In the event of a plurality of light emitting diodes being present, they may emit light in the same color or in different colors. A color may be monochromatic (e.g. red, green, blue, etc.) or multichromatic (e.g. white). The light emitted by the at least one light emitting diode may also be infrared light (IR LED) or ultraviolet light (UV LED). A plurality of light emitting diodes may generate a mixed light; e.g. a white mixed light. The at least one light emitting diode may contain at least one wavelength-converting phosphor (conversion LED). The phosphor may alternatively or additionally be arranged in a manner remote from the light emitting diode (“Remote Phosphor”). The at least one light emitting diode may be present in the form of at least one individually housed light emitting diode or in the form of at least one LED chip. A plurality of LED chips may be mounted on a common substrate (“Submount”). The at least one light emitting diode may be equipped with at least one dedicated and/or common optical unit for beam guiding, e.g. at least one Fresnel lens, collimator, and so on. Instead or in addition to inorganic light emitting diodes, e.g. on the basis of InGaN or AlInGaP, generally organic LEDs (OLEDs, e.g. polymer OLEDs) may also be used. Alternatively, the at least one semiconductor light source may include e.g. at least one diode laser.

The thermal power loss Pth may be understood to mean, in various embodiments, that power which is generated or emitted in the form of heat during operation of the at least one semiconductor light source.

The electrical power Pe of the at least one semiconductor light source may be, in various embodiments, an impressed electrical power for the at least one semiconductor light source.

In one configuration, determining the light power Pl includes forming a difference between the electrical power Pe and the thermal power loss Pth. As a result, the light power Pl may be determined in a particularly simple manner.

In one development, the light power Pl is determined with the aid of the relationship

Pl=Pe−Pth (1)

If, by way of example, the thermal power loss Pth is 60% of the impressed electrical power Pe, according to equation (1) this corresponds to a light power of 40% of the electrical power Pe.

In one configuration, determining the thermal power loss Pth includes determining a temperature difference ΔT between a temperature T0 at the beginning of operation of the lighting device (“switch-on instant”) and a temperature Tb in a thermally settled state of the lighting device (“thermalization”), e.g. in accordance with ΔT=Tb−T0. In thermally settled operation of the lighting device, a temperature T at the semiconductor light sources may not or no longer significantly rise. As a result, using the thermal resistance Rth it is possible to determine the thermal power loss Pth, e.g. in accordance with

Pth=ΔT/Rth. (2)

It can take e.g. a few minutes to reach the thermally settled state.

In a further configuration, a, e.g. experimentally, predetermined thermal resistance Rth is used for determining the thermal power loss Pth.

In yet another configuration, a thermal resistance Rth is determined in situ (e.g. during operation of the installed lighting device) for determining the thermal power loss Pth. This affords the advantage that in the case of the thermal resistance, an installation situation of the lighting device, e.g. the ambient temperature thereof, can be concomitantly taken into account. The determination in situ can be carried out for example by means of measurements at slightly different predefined operating currents of the lighting device.

In a development that is advantageous for further increasing a precision with which the thermal power loss Pth is determined, it is purged of any influence of a thermal power loss of an electronic unit possibly present. This may be advantageous e.g. if the electronic unit can influence a temperature measurement for the at least one semiconductor light source. This may be the case, for example, if the at least one semiconductor light source and also the electronic unit are connected to a common heat sink (e.g. a cooling body) on which a temperature measurement is also carried out.

In various embodiments, the thermal power loss of the electronic unit is determined from its electrical power. In various embodiments, the thermal power loss of the electronic unit may be equated with its electrical power since generally only heat is generated by the electronic unit during its operation.

The electrical power of the electronic unit may be predetermined or determined in situ during operation.

In one configuration, furthermore, determining the electrical power Pe includes determining a voltage U applied to the at least one semiconductor light source for the operation thereof and/or an electric current I through the at least one semiconductor light source, that is to say in particular by means of the relationship Pe=U·I.

In various embodiments, the electrical power Pe impressed into the at least one semiconductor light source has been purged of any electrical power impressed into an electronic unit possibly present, for example by forming the difference between (measured) electrical power impressed into the entire lighting device minus the (previously known or measured) electrical power impressed into the electronic unit. This may be advantageous in various embodiments if a measurement of the electrical power is carried out on a common electrical line or on the lighting device as such.

Alternatively, an electrical power of the electronic unit possibly present may be disregarded, for example if the measurement of the electrical power Pe is carried out (e.g. by means of a voltage measurement) only on the at least one semiconductor light source and/or if the electrical power of the electronic unit is comparatively low.

In various embodiments, the electric current I impressed into the at least one semiconductor light source is constant. This may be achieved for example by means of a current stabilizer circuit. This affords the advantage that the electrical power Pe can be determined by means of a simple voltage measurement and can be regulated or set by means of a single voltage regulation. The current I may be set or regulated in particular to a predetermined, in particular variable, desired value.

In one configuration, moreover, determining the light power is followed by a step of varying or changing the electrical power for setting the light power to a predetermined (desired or normal) value or range of values. As a result, a light power can be kept constant or at least in a predetermined range over a lifetime of the at least one semiconductor light source. As a result, in turn, when a lighting device is present which includes semiconductor light sources which emit light of different colors for forming a mixed light, a cumulative color locus of the mixed light can be kept constant or in a predetermined range, if appropriate with total light power or brightness changed in a targeted manner (“color locus calibration”).

In one configuration, generally, the method is carried out for a plurality of groups of semiconductor light sources, e.g. emitting in different colors. The plurality of groups of semiconductor light sources may include light emitting diodes (LEDs), for example, which emit light colored red, green and/or blue. Alternatively, it is possible for example to calibrate groups of semiconductor light sources which emit greenish-white (mint) light and/or amber light, if appropriate additionally with at least one LED that emits red or orange light, e.g. in the context of the “Brilliant Mix” concept from OSRAM Opto Semiconductors GmbH. This configuration generally makes it possible to keep a cumulative color locus of the mixed light constant or in a predetermined range, if appropriate with total light power or brightness changed in a targeted manner. In order to carry out the method among a plurality of groups of semiconductor light sources, it may be applied to said groups successively, in various embodiments.

Generally, a calibration or implementation of the method may be performed on the basis of a brightness determined from the light power and assessed by eye. For this purpose, the step of determining the light power may be followed by a step of determining the eye-assessed brightness from the light power, e.g. by means of a corresponding characteristic curve or table.

In one development, the method is initiated independently by the lighting device, e.g. at predetermined intervals in an operating period (e.g. every one thousand hours), after a switch-on, on a predetermined date, etc.

In an additional or alternative development the method is initiated externally, for example is triggered manually (e.g. by means of a corresponding switch) or by an external control command (e.g. via a DALI or DMX connection), but is carried out as such by the lighting device.

Generally, this method may be combined with a further method which compensates for a different temperature dependence of the brightness of semiconductor light sources emitting light in different colors (e.g. with an InGaAlP chip and/or InGaN chip), e.g. between a switch-on instant and a thermally compensated or settled state.

Various embodiments provide a lighting device including at least one semiconductor light source, wherein the lighting device is designed for carrying out the method as described above. The lighting device may be embodied analogously to the method and have the same advantages.

The lighting device may include for this purpose in various embodiments a (at least one) voltage measuring device and a (at least one) temperature measuring device.

In one configuration, the lighting device is designed for independently carrying out the method and includes for this purpose a correspondingly designed electronic control unit, e.g. driver.

Alternatively or additionally, the lighting device may be designed for carrying out the method (in a distributed manner) together with an external control device.

The lighting device may be for example a luminaire, a lamp or a lighting module.

Various embodiments provide a system including at least one lighting device as described above and including an external control device, wherein the system is designed for carrying out the method as described above in a manner distributed with respect to said system. This enables a simpler and less expensive lighting device. Moreover, this makes it possible, in a simple manner, to coordinate a light emission of a plurality of luminaires with one another, e.g. with regard to a brightness or a color locus.

The FIGURE shows a lighting device in the form of a luminaire 11 including a plurality of semiconductor light sources in the form of LEDs 12, 13, 14, The LEDs 12-14 here form three groups of LEDs which emit light of different colors, e.g. a first group including at least one “red” LED 12, emitting red light, a second group including at least one “green” LED 13, emitting green light, and a third group including at least one “blue” LED 14, emitting blue light. The light from the LEDs 12-14 generates an, e.g. white, mixed light, the desired cumulative color locus of which should be complied with as precisely as possible.

The luminaire 11 includes an electronic control unit 15, e.g. a driver, which drives the LEDs 12-14 and supplies them with electrical signals e.g. in a targeted manner. For this purpose, the electronic control unit 15 has a current stabilizer circuit, such that the current impressed into the groups of LEDs 12-14 is at least substantially constant, that is to say I=const. holds true. In this case, the current for different groups of LEDs 12-14 can be identical (e.g. in the case of the series connection thereof) or different (e.g. in the case of the parallel connection thereof).

The LEDs 12-14 and the electronic control unit 15 are arranged on a common cooling body (not illustrated). The cooling body has, in particular, a thermal resistance that is practically constant for the operation of the luminaire 11.

The luminaire 11 furthermore includes at least one, in various embodiments exactly one, voltage measuring device 16 for measuring a voltage U present at the respective groups of LEDs 12-14.

The luminaire 11 also includes at least one temperature measuring device 17, e.g. including at least one temperature sensor, for measuring S2 a temperature T present at the groups of LEDs 12-14. The luminaire 11 may include for example exactly one temperature measuring device 17, in particular since the groups of LEDs 12 to 14 are fitted on a common cooling body (not illustrated). On the cooling body, the temperature T of the LEDs 12-14 may also be sensed by means of the temperature measuring device 17.

When the luminaire 11 is switched on, in order to carry out the method, firstly a step S1 involves measuring an associated temperature T0 and then, e.g. after a few minutes, a temperature Tb in a thermally settled state of a currently selected group of LEDs 12-14. Moreover, e.g. at the same time as or with a small distance of time with respect to the temperature Tb, the voltage U present at the group of LEDs 12-14 currently under consideration is measured in a step S2.

In a step S3, the electronic control unit 15 determines therefrom the thermal power loss Pth of the currently selected group of LEDs 12-14 in accordance with Pth=(Tb−T0)/Rth=ΔT/Rth (where Rth is previously known or determined in situ). If an influence of an electronic unit, e.g. the electronic control unit 15, is present during a measurement of the temperature Tb in step S2, in a step S4 it is possible to subtract its electrical power corresponding to its thermal power loss.

In a step S5, furthermore, for the group of LEDs 12-14 currently under consideration, the electrical power thereof Pe=U·I is determined by means of the electronic control unit 15, where I is assumed to be constant (arbitrarily settable, but then chosen to be fixed).

From Pth and Pe, in a step S6 the light power Pl of the group of LEDs 12-14 under consideration is determined in accordance with Pl=Pe−Pth by means of the electronic control unit 15.

In a subsequent step S7, by means of the electronic control unit 15, a deviation of the light power Pl determined from a desired light power is determined and the power Pe applied to the group of LEDs 12-14 currently under consideration is readjusted in the event of a deviation. The luminaire 11 is therefore configured for automatically carrying out method steps S1 to S7. The method may be initiated internally, e.g. by means of a rule stored in the electronic control unit 15. Alternatively or additionally, the electronic control unit 15 may be communicatively connected to an external control device 18, via which it receives a command for initiating the method.

Steps S1 to S7 are carried out successively for each of the groups of LEDs 12-14. The initial temperature T0 at the common cooling body is the same for all groups of LEDs 12-14 and therefore need only be measured once. The thermal power loss of the electronic control unit 15 is subtracted each time. In various embodiments, itIt is provided to measure the thermal power loss of the electronic control unit 15 for this purpose since it can be different depending on the operation of the groups of LEDs 12-14.

Although the invention has been more specifically illustrated and described in detail by means of the exemplary embodiment shown, the invention is nevertheless not restricted thereto, and other variations can be derived therefrom by a person skilled in the art, without departing from the scope of protection of the invention.

In this regard, the method may proceed at least in part (in a distributed manner) also on a system including at least one luminaire 11 and including the eternal control device 18 (e.g. a DMX or DALI control device). For this purpose, the at least one luminaire 11 may measure for example the temperature T and the voltage U analogously to steps S1 and S2, respectively, and communicate the measured values to the external control device 18, as indicated by the double-headed arrow. The external control device 18 may then calculate the light power Pl therefrom and send corresponding control data for calibrating the LEDs 12 to 14 of the luminaire 11 to the luminaire 11, e.g. analogously to step S7.

In general, “a”, “one”, etc. can be understood to mean a singular or a plural, in particular in the sense of “at least one” or “one or a plurality”, etc., as long as this is not explicitly excluded, e.g. by the expression “exactly one”, etc.

Moreover, a numerical indication can encompass exactly the indicated number and also a customary tolerance range, as long as this is not explicitly excluded.

### LIST OF REFERENCE SIGNS

11 Luminaire

12 red LED

13 green LED

14 blue LED

15 Electronic control unit

16 Voltage measuring device

17 Temperature measuring device

18 External control device

Pl Light power

Pe Electrical power

Pe; L Electrical power of the luminaire

Pth Thermal power loss

S1 Step

S2 Step

S3 Step

S4 Step

S5 Step

S6 Step

S7 Step

T Temperature

T0 Temperature at the switch-on instant

Tb Temperature after thermalization

U Voltage

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for calibrating a lighting device, the lighting device comprising at least one semiconductor light source, the method comprising:
determining a thermal power loss of the at least one semiconductor light source;
determining an electrical power of the at least one semiconductor light source; and
determining a light power of the at least one semiconductor light source from the electrical power and the thermal power loss.

2. The method of claim 1,
wherein determining the thermal power loss comprises determining a temperature difference between a temperature at the beginning of operation of the lighting device and a temperature in thermally settled operation of the lighting device.

3. The method of claim 1,
wherein a predetermined thermal resistance is used for determining the thermal power loss.

4. The method of claim 1,
wherein a thermal resistance is determined in situ for determining the thermal power loss.

5. The method of claim 1,
wherein determining the electrical power comprises determining at least one of a voltage applied to the at least one semiconductor light source for the operation thereof or an electric current through the at least one semiconductor light source.

6. The method of claim 1,
wherein determining the light power comprises forming a difference between the thermal power loss and the electrical power.

7. The method of claim 1,
wherein determining the light power is followed by varying the electrical power for setting the light power to a predetermined value or range of values.

8. The method of claim 1,
wherein the method is carried out for a plurality of groups of semiconductor light sources.

9. The method of claim 8,
wherein the method is carried out for a plurality of groups of semiconductor light sources of different colors.

10. A lighting device, comprising:
at least one semiconductor light source;
a voltage measuring device; and
a temperature measuring device;
wherein the lighting device is configured to carry out a method for calibrating the lighting device, the method comprising:
determining a thermal power loss of the at least one semiconductor light source;
determining an electrical power of the at least one semiconductor light source; and
determining a light power of the at least one semiconductor light source from the electrical power and the thermal power loss.

11. The lighting device of claim 10,
wherein the lighting device is configured to independently carry out the method;
the lighting device further comprising a correspondingly designed electronic control unit.

12. A system, comprising:
at least one lighting device, comprising:
at least one semiconductor light source;
a voltage measuring device; and
a temperature measuring device;
wherein the lighting device is configured to carry out a method for calibrating the lighting device, the method comprising:
determining a thermal power loss of the at least one semiconductor light source;
determining an electrical power of the at least one semiconductor light source; and
determining a light power of the at least one semiconductor light source from the electrical power and the thermal power loss;
an external control device;
wherein the system is configured to carry out the method in a distributed manner with respect to said system.
